(19) United States
(12) Patent Application Publication
(10) Pub. No.: US 2023/0197562 A1
(43) Pub. Date: Jun. 22, 2023

(54) CHIP DEVICE

(71) Applicant: SUNONWEALTH ELECTRIC MACHINE INDUSTRY CO., LTD., Kaohsiung City (TW)

(72) Inventors: Chi-Ting YEH, Kaohsiung City (TW); Ya Hui CHEN, Kaohsiung City (TW)

(21) Appl. No.: 18/068,003

(22) Filed: Dec. 19, 2022

(30) Foreign Application Priority Data
Dec. 20, 2021 (TW) 110215140

(51) Int. Cl. H01L 23/42; H01L 23/04; H01L 23/367

(52) U.S. Cl. CPC H01L 23/42; H01L 23/041; H01L 23/367

(57) ABSTRACT

A chip device is provided. The chip device includes a substrate, at least one chip, a sealing component, a heat-conducting medium, a barrier, and a heat dissipation device. The at least one chip is disposed over a first surface of the substrate and has a heat transfer surface. The sealing component covers the at least one chip and has a heat transfer area thermal contacting the heat transfer surface of the at least one chip. The heat-conducting medium is disposed over the heat transfer area of the sealing component. The barrier is disposed around and blocks the heat-conducting medium. The heat dissipation device is disposed over the heat transfer area of the sealing component and on the heat-conducting medium. The chip device can block the heat-conducting medium through the barrier to prevent the heat-conducting medium from overflowing or losing between the sealing component and the heat dissipation device.

### BACKGROUND

### 1. Field of the Disclosure

The present disclosure relates to a chip device, and to a chip device including a barrier.

### 2. Description of the Related Art

It is known that thermal paste is applied between a chip and a sealing member or between the sealing member and a heat dissipation device to proceed with heat conduction. If the thermal paste overflows from between the chip and the sealing member or from between the sealing member and the heat dissipation device, it will cause poor heat conduction. If the thermal paste flows into a cooling liquid of an immersion cooling system, it will cause the cooling liquid to deteriorate or its thermal performance to be reduced.

### SUMMARY

In some embodiments, a chip device includes a substrate, at least one chip, a sealing component, a heat-conducting medium, a barrier, and a heat dissipation device. The substrate has a first surface and a second surface opposite to the first surface. The at least one chip is disposed over the first surface of the substrate and has a heat transfer surface. The sealing component covers the at least one chip and has a heat transfer area thermal contacting the heat transfer surface of the at least one chip. The heat-conducting medium is disposed over the heat transfer area of the sealing component. The barrier is disposed around and blocks the heat-conducting medium. The heat dissipation device is disposed over the heat transfer area of the sealing component and on the heat-conducting medium.

In some embodiments, a chip device includes a substrate, at least one chip, a sealing component, a heat-transferring medium, and an isolator. The substrate has a first surface and a second surface opposite to the first surface. The at least one chip is disposed over the first surface of the substrate and has a heat transfer surface. The sealing component covers the at least one chip and has a heat transfer area. The heat-transferring medium is disposed between the heat transfer area of the sealing component and the heat transfer surface of the at least one chip. The isolator is disposed around and isolates the heat-transferring medium.

The chip device can block the heat-conducting medium through the barrier to prevent the heat-conducting medium from overflowing between the sealing component and the heat dissipation device. The chip device can also isolate the heat-transferring medium through the isolator to prevent the heat-transferring medium from overflowing between the sealing component and the chip. Thus, it can avoid the situation of poor heat conduction. Also, the heat-conducting medium or the heat-transferring medium will not flow into the cooling liquid, thereby maintaining the quality of the cooling liquid and avoiding a decrease in the thermal performance of the cooling liquid.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a chip device according to some embodiments of the present disclosure.

FIG. 2 illustrates a cross-sectional view of a chip device according to some embodiments of the present disclosure.

FIG. 3 illustrates a cross-sectional view of a chip device according to some embodiments of the present disclosure.

FIG. 4 illustrates a cross-sectional view of a chip device according to some embodiments of the present disclosure.

FIG. 5 illustrates a cross-sectional view of a chip device according to some embodiments of the present disclosure.

FIG. 6 illustrates a cross-sectional view of a chip device according to some embodiments of the present disclosure.

FIG. 7 illustrates a cross-sectional view of a chip device according to some embodiments of the present disclosure.

FIG. 8 illustrates a cross-sectional view of a chip device according to some embodiments of the present disclosure.

FIG. 9 illustrates a cross-sectional view of a chip device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

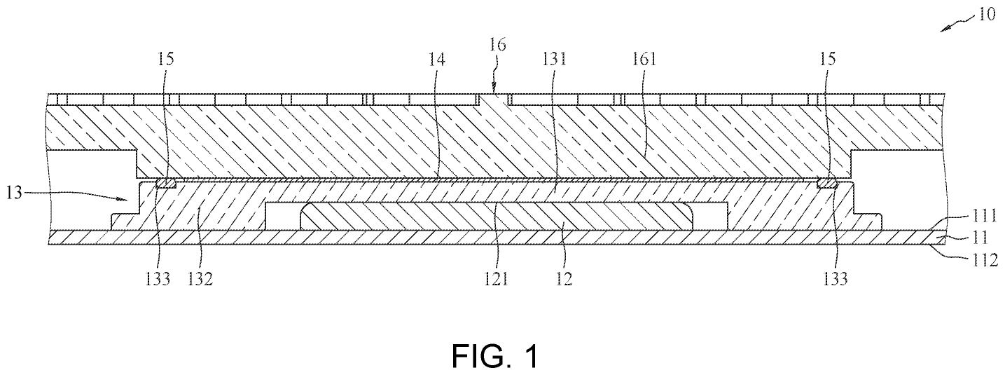

FIG. 1 illustrates a cross-sectional view of a chip device 10 according to some embodiments of the present disclosure. In some embodiments, as shown in FIG. 1, the chip device 10 can include a substrate 11, at least one chip 12, a sealing component 13, a heat-conducting medium 14, a barrier 15, and a heat dissipation device 16. The chip device 10 can be disposed in an environment with a fluid such as non-conductive cooling liquid, non-conductive working fluid, etc., for example, an immersion cooling system, to improve the heat dissipation of the chip device 10, but not limited to the above. The chip device 10 can also be applied in a cooling system without cooling liquid.

In some embodiments, the substrate 11 can have a first surface 111 and a second surface 112. The second surface 112 is opposite to the first surface 111. The at least one chip 12 can be disposed over the first surface 111 of the substrate 11. The at least one chip 12 can have a heat transfer surface 121. The heat transfer surface 121 can be a surface on which the at least one chip 12 transfers the generated heat.

In some embodiments, the sealing component 13 can cover the at least one chip 12. The sealing component 13 can have a heat transfer area 131. The heat transfer area 131 can thermal contact the heat transfer surface 121 of the at least one chip 12. In some embodiments, the heat transfer area 131 can directly contact the heat transfer surface 121 of the at least one chip 12. In some embodiments, a thermal paste, a thermal pad, or a thermal glue can be disposed between the heat transfer area 131 and the heat transfer surface 121 of the at least one chip 12 to improve heat conduction effects.

In some embodiments, the heat-conducting medium 14 can be disposed over the heat transfer area 131 of the sealing component 13. The heat-conducting medium 14 can be, for example, thermal paste, thermal pad, or thermal glue. In some embodiments, the barrier 15 can be disposed around the heat-conducting medium 14. The barrier 15 can block the heat-conducting medium 14. The barrier 15 can be an O-ring. The O-ring can be rubber or silicone. In some embodiments, the heat dissipation device 16 can be disposed over the heat transfer area 131 of the sealing component 13 and on the heat-conducting medium 14. The heat dissipation device 16 can include a heat conduction area 161 disposed over the heat transfer area 131 of the sealing component 13. The heat dissipation device 16 can be, for example, a fin heat sink, a water cooling plate, or a vapor chamber.

Therefore, the barrier 15 can prevent the heat-conducting medium 14 from overflowing between the sealing component 13 and the heat dissipation device 16 and avoid the situation of poor heat conduction caused by the loss of the heat-conducting medium 14. If the chip device 10 is applied in the environment with the fluid (e.g., the non-conductive cooling liquid), the heat-conducting medium 14 will not flow into the cooling liquid, thereby maintaining the quality of the cooling liquid and avoiding a decrease in the thermal performance of the cooling liquid.

In some embodiments, the sealing component 13 can include a frame 132. The frame 132 can be disposed at a periphery of the heat transfer area 131 and on the substrate 11. The frame 132 of the sealing component 13 can have a first ring trench 133 facing the heat dissipation device 16. The barrier 15 can be disposed in the first ring trench 133 to block the heat-conducting medium 14 and prevent the heat-conducting medium 14 from overflowing or losing.

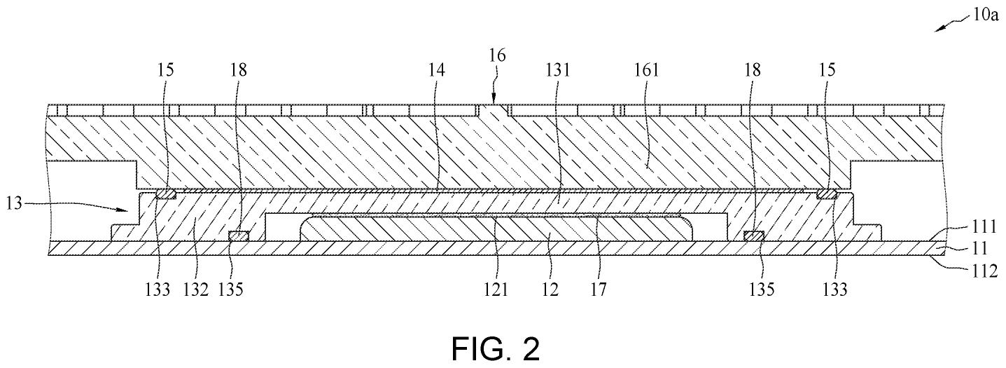

FIG. 2 illustrates a cross-sectional view of a chip device 10a according to some embodiments of the present disclosure. In some embodiments, as shown in FIG. 2, a heat-transferring medium 17 can be between the heat transfer area 131 of the sealing component 13 and the heat transfer surface 121 of the at least one chip 12. An isolator 18 can be disposed around the heat-transferring medium 17. The isolator 18 can isolate the heat-transferring medium 17. In some embodiments, the heat-transferring medium 17 can be, for example, thermal paste, thermal pad, or thermal glue. The isolator 18 can be an O-ring. The O-ring can be rubber or silicone. In some embodiments, the frame 132 of the sealing component 13 can have a first ring groove 135 facing the substrate 11. The isolator 18 can be disposed in the first ring groove 135 to isolate the heat-transferring medium 17 and prevent the heat-transferring medium 17 from overflowing or losing.

Therefore, the isolator 18 can isolate the heat-transferring medium 17 and prevent the heat-transferring medium 17 from overflowing between the sealing component 13 and the chip 12, which can avoid the situation of poor heat conduction caused by the loss of the heat-transferring medium 17. If the chip device 10a is applied in the environment with the fluid (e.g., the non-conductive cooling liquid), the heat-transferring medium 17 will not flow into the cooling liquid, thereby maintaining the quality of the cooling liquid and avoiding a decrease in the thermal performance of the cooling liquid.

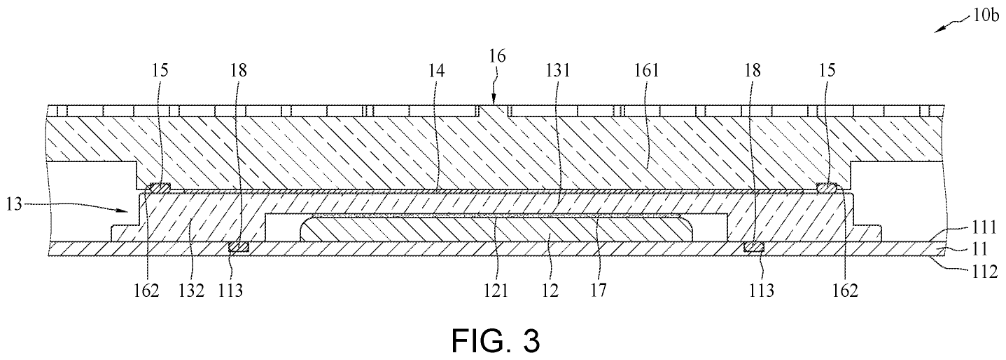

FIG. 3 illustrates a cross-sectional view of a chip device 10b according to some embodiments of the present disclosure. In some embodiments, as shown in FIG. 3, the heat dissipation device 16 can have a second ring trench 162 facing the sealing component 13. The barrier 15 can be disposed in the second ring trench 162 to block the heat-conducting medium 14 and prevent the heat-conducting medium 14 from overflowing or losing. In some embodiments, the substrate 11 can have a second ring groove 113 facing the sealing component 13. The isolator 18 can be disposed in the second ring groove 113 to isolate the heat-transferring medium 17 and prevent the heat-transferring medium 17 from overflowing or losing. Thus, utilization of the barrier 15 and the isolator 18 can also have the effects mentioned above.

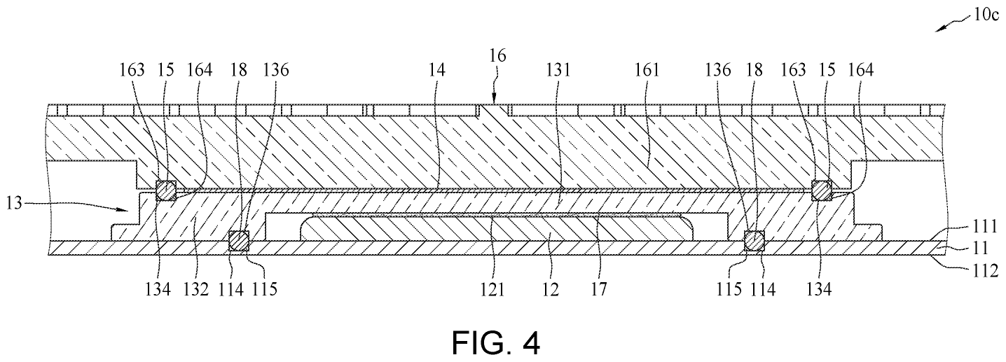

FIG. 4 illustrates a cross-sectional view of a chip device 10c according to some embodiments of the present disclosure. In some embodiments, as shown in FIG. 4, the frame 132 of the sealing component 13 can have a first corresponding groove 134. The heat dissipation device 16 can have a second corresponding groove 163. The first corresponding groove 134 can correspond to the second corresponding groove 163 to constitute an accommodating space 164. The accommodating space 164 is configured to accommodate the barrier 15. The barrier 15 can be used to block the heat-conducting medium 14 and prevent the heat-conducting medium 14 from overflowing or losing. In some embodiments, the frame 132 of the sealing component 13 can have a first relative groove 136. The substrate 11 can have a second relative groove 114. The first relative groove 136 can correspond to the second relative groove 114 to constitute an arranging space 115. The arranging space 115 is configured to arrange the isolator 18. The isolator 18 can be used to isolate the heat-transferring medium 17 and prevent the heat-transferring medium 17 from overflowing or losing. Thus, utilization of the barrier 15 and the isolator 18 can also have the effects mentioned above.

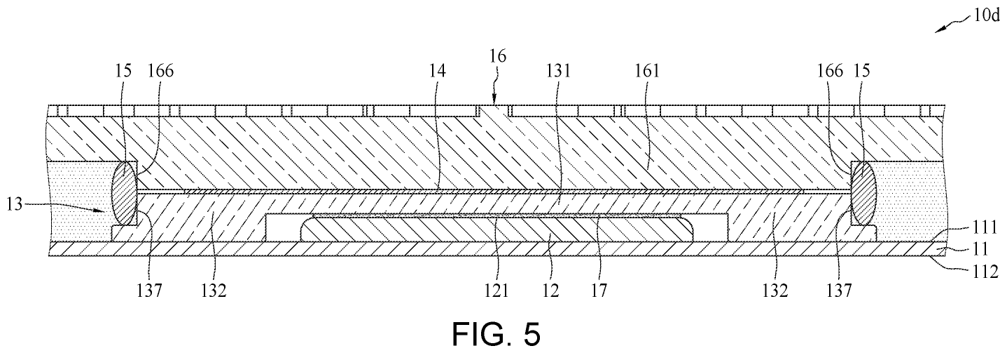

FIG. 5 illustrates a cross-sectional view of a chip device 10d according to some embodiments of the present disclosure. In some embodiments, as shown in FIG. 5, a first outer edge 166 of the heat conduction area 161 of the heat dissipation device 16 can be aligned with a second outer edge 137 of the frame 132 of the sealing component 13. The barrier 15 can be disposed at the first outer edge 166 of the heat conduction area 161 of the heat dissipation device 16 and the second outer edge 137 of the frame 132 of the sealing component 13. The barrier 15 can be used to block the heat-conducting medium 14 and prevent the heat-conducting medium 14 from overflowing or losing. Thus, utilization of the barrier 15 can also have the effects mentioned above.

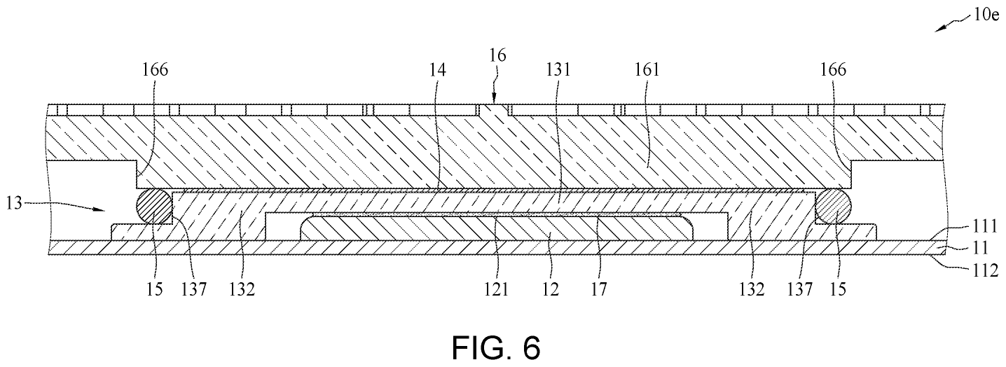

FIG. 6 illustrates a cross-sectional view of a chip device 10e according to some embodiments of the present disclosure. In some embodiments, as shown in FIG. 6, the first outer edge 166 of the heat conduction area 161 of the heat dissipation device 16 can extend beyond the second outer edge 137 of the frame 132 of the sealing component 13. The barrier 15 can be disposed under the heat conduction area 161 of the heat dissipation device 16 and at the second outer edge 137 of the frame 132 of the sealing component 13. The barrier 15 can be used to block the heat-conducting medium 14 and prevent the heat-conducting medium 14 from overflowing or losing. Thus, utilization of the barrier 15 can also have the effects mentioned above.

In some embodiments, the sealing component 13 can further include an encapsulation structure (not shown in the drawings). The encapsulation structure is configured to encapsulate the at least one chip 12. The encapsulation structure can be disposed outside the frame 132. The barrier 15 can be disposed outside the encapsulation structure to block the heat-conducting medium 14 and prevent the heat-conducting medium 14 from overflowing or losing.

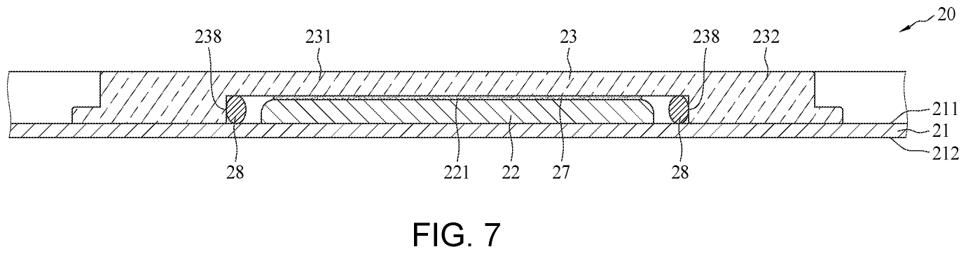

FIG. 7 illustrates a cross-sectional view of a chip device 20 according to some embodiments of the present disclosure. In some embodiments, as shown in FIG. 7, the chip device 20 can include a substrate 21, at least one chip 22, a sealing component 23, a heat-transferring medium 27, and an isolator 28. The substrate 21 can have a first surface 211 and a second surface 212. The second surface 212 is opposite to the first surface 211. The at least one chip 22 can be disposed over the first surface 211 of the substrate 21. The at least one chip 22 can have a heat transfer surface 221. The heat transfer surface 221 can be a surface on which the at least one chip 22 transfers the generated heat.

In some embodiments, the sealing component 23 can cover the at least one chip 22. The sealing component 23 can have a heat transfer area 231. The heat-transferring medium 27 can be disposed between the heat transfer area 231 of the sealing component 23 and the heat transfer surface 221 of the at least one chip 22. The isolator 28 can be disposed around the heat-transferring medium 27. The isolator 28 can isolate the heat-transferring medium 27. In some embodiments, the heat-transferring medium 27 can be, for example, thermal paste, thermal pad, or thermal glue.

Therefore, the isolator 28 can isolate the heat-transferring medium 27 and prevent the heat-transferring medium 27 from overflowing between the sealing component 23 and the chip 22, which can avoid the situation of poor heat conduction caused by the loss of the heat-transferring medium 27. If the chip device 20 is applied in the environment with the fluid (e.g., the non-conductive cooling liquid), the heat-transferring medium 27 will not flow into the cooling liquid, thereby maintaining the quality of the cooling liquid and avoiding a decrease in the thermal performance of the cooling liquid.

In some embodiments, the sealing component 23 can include a frame 232. The frame 232 can be disposed at a periphery of the heat transfer area 231 and on the substrate 21. The frame 232 of the sealing component 23 can include an inner ring wall 238. The isolator 28 can be disposed at the inner ring wall 238. The isolator 28 can be used to isolate the heat-transferring medium 27 and prevent the heat-transferring medium 27 from overflowing or losing, so as to have the effects mentioned above.

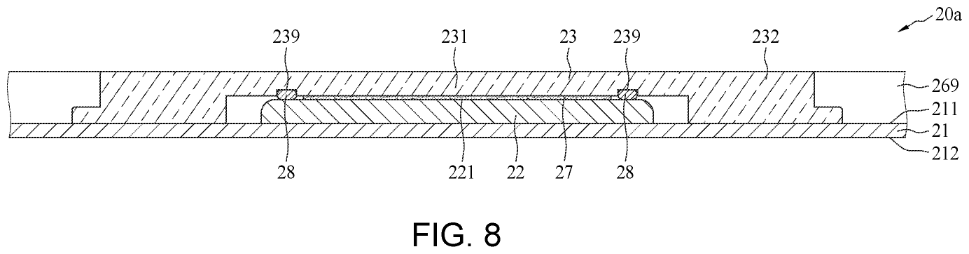

FIG. 8 illustrates a cross-sectional view of a chip device 20a according to some embodiments of the present disclosure. In some embodiments, as shown in FIG. 8, the heat transfer area 232 of the sealing component 23 can have an accommodating groove 239 facing the heat transfer surface 221 of the at least one chip 22. The isolator 28 can be disposed in the accommodating groove 239 to isolate the heat-transferring medium 27 and prevent the heat-transferring medium 27 from overflowing or losing, so as to have the effects mentioned above.

In some embodiments, as shown in FIG. 2 through FIG. 4, in the absence of the heat-conducting medium 14, the barrier 15 and the heat dissipation device 16, the isolator 18 of the present disclosure can be disposed in the first ring groove 135 (FIG. 2), the second ring groove 113 (FIG. 3) or the arranging space 115 (FIG. 4) constituted by the first relative groove 136 and the second relative groove 114 to isolate the heat-transferring medium 17 and prevent the heat-transferring medium 17 from overflowing or losing, so as to have the effects mentioned above.

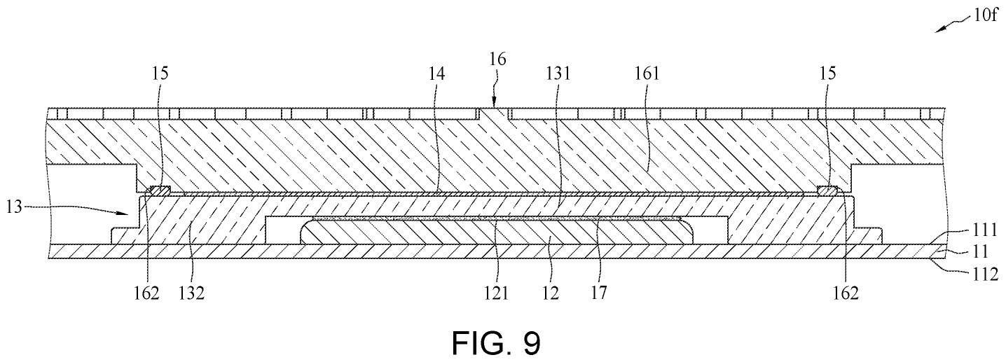

FIG. 9 illustrates a cross-sectional view of a chip device 10f according to some embodiments of the present disclosure. In some embodiments, as shown in FIG. 9, the heat dissipation device 16 of the chip device 10f can have the second ring trench 162 facing the sealing component 13. The barrier 15 can be disposed in the second ring trench 162 to block the heat-conducting medium 14 and prevent the heat-conducting medium 14 from overflowing or losing, so as to have the effects mentioned above.

While several embodiments of the present disclosure have been illustrated and described, various modifications and improvements can be made by those skilled in the art. The embodiments of the present disclosure are therefore described in an illustrative but not in a restrictive sense. It is intended that the present disclosure should not be limited to the particular forms as illustrated and that all modifications which maintain the spirit and scope of the present disclosure are within the scope defined in the appended claims.

What is claimed is:

1. A chip device, comprising:
a substrate having a first surface and a second surface opposite to the first surface;
at least one chip disposed over the first surface of the substrate and having a heat transfer surface;
a sealing component covering the at least one chip and having a heat transfer area thermal contacting the heat transfer surface of the at least one chip;
a heat-conducting medium disposed over the heat transfer area of the sealing component;
a barrier disposed around and blocking the heat-conducting medium; and
a heat dissipation device disposed over the heat transfer area of the sealing component and on the heat-conducting medium.

2. The chip device of claim 1, wherein the sealing component includes a frame disposed at a periphery of the heat transfer area and on the substrate.

3. The chip device of claim 2, wherein the frame of the sealing component has a ring trench facing the heat dissipation device, and the barrier is disposed in the ring trench.

4. The chip device of claim 2, wherein the heat dissipation device has a ring trench facing the sealing component, and the barrier is disposed in the ring trench.

5. The chip device of claim 2, wherein the sealing component has a first corresponding groove, the heat dissipation device has a second corresponding groove, and the first corresponding groove corresponds to the second corresponding groove to constitute an accommodating space configured to accommodate the barrier.

6. The chip device of claim 2, wherein the barrier is disposed outside the frame.

7. The chip device of claim 6, wherein the heat dissipation device includes a heat conduction area disposed over the heat transfer area of the sealing component and the frame.

8. The chip device of claim 7, wherein a first outer edge of the heat conduction area is aligned with a second outer edge of the frame of the sealing component, and the barrier is disposed at the first outer edge of the heat conduction area and the second outer edge of the frame.

9. The chip device of claim 7, wherein a first outer edge of the heat conduction area extends beyond a second outer edge of the frame of the sealing component, and the barrier is disposed under the heat conduction area and at the second outer edge of the frame.

10. The chip device of claim 2, further comprising a heat-transferring medium and an isolator, wherein the heat-transferring medium is between the heat transfer area of the sealing component and the heat transfer surface of the at least one chip, and the isolator is disposed around and isolates the heat-transferring medium.

11. The chip device of claim 10, wherein the frame of the sealing component has a ring groove facing the substrate, and the isolator is disposed in the ring groove.

12. The chip device of claim 10, wherein the substrate has a ring groove facing the sealing component, and the isolator is disposed in the ring groove.

13. The chip device of claim 10, wherein the frame of the sealing component has a first relative groove, the substrate has a second relative groove, and the first relative groove corresponds to the second relative groove to constitute an arranging space configured to arrange the isolator.

14. The chip device of claim 10, wherein the frame of the sealing component includes an inner ring wall, and the isolator is disposed at the inner ring wall.

15. The chip device of claim 10, wherein the heat transfer area of the sealing component has an accommodating groove facing the heat transfer surface of the at least one chip, and the isolator is disposed in the accommodating groove.

16. A chip device, comprising:
a substrate having a first surface and a second surface opposite to the first surface;
at least one chip disposed over the first surface of the substrate and having a heat transfer surface;
a sealing component covering the at least one chip and having a heat transfer area;
a heat-transferring medium disposed between the heat transfer area of the sealing component and the heat transfer surface of the at least one chip; and
an isolator disposed around and isolating the heat-transferring medium.

17. The chip device of claim 16, wherein the sealing component includes a frame disposed at a periphery of the heat transfer area and on the substrate.

18. The chip device of claim 17, wherein the frame of the sealing component has a ring groove facing the substrate, and the isolator is disposed in the ring groove.

19. The chip device of claim 17, wherein the substrate has a ring groove facing the sealing component, and the isolator is disposed in the ring groove.

20. The chip device of claim 17, wherein the frame of the sealing component has a first relative groove, the substrate has a second relative groove, and the first relative groove corresponds to the second relative groove to constitute an arranging space configured to arrange the isolator.

21. The chip device of claim 17, wherein the frame of the sealing component includes an inner ring wall, and the isolator is disposed at the inner ring wall.

22. The chip device of claim 17, wherein the heat transfer area of the sealing component has an accommodating groove facing the heat transfer surface of the at least one chip, and the isolator is disposed in the accommodating groove.
